(19) United States
(12) Patent Application Publication
(10) Pub. No.: US 2013/0100755 A1
(43) Pub. Date: Apr. 25, 2013

(54) SEMICONDUCTOR MEMORY DEVICE IMPLEMENTING COMPREHENSIVE PARTIAL ARRAY SELF REFRESH SCHEME

(71) Applicant: SAMSUNG ELECTRONICS CO., LTD., Suwon-Si (KR)

(72) Inventors: Jae-youn YOUN, Seoul (KR); Hyo-chang KIM, Gwangju-si (KR); Sang-jae RHEE, Seognam-si (KR)

(73) Assignee: SAMSUNG ELECTRONICS CO., LTD., Suwon-Si (KR)

(21) Appl. No.: 13/653,799

(22) Filed: Oct. 17, 2012

Related U.S. Application Data
(60) Provisional application No. 61/549,836, filed on Oct. 21, 2011.

(30) Foreign Application Priority Data
Feb. 29, 2012 (KR) 10-2012-0021406

(51) Int. Cl. G11C 7/00

(52) U.S. Cl. 365/222

(57) ABSTRACT

A semiconductor memory device performing a comprehensive partial self refresh (CPSR) scheme, in which a CPSR operation of not performing a self refresh operation on the segments included in each bank is disclosed. The semiconductor memory device includes a mask information register configured to generate mask information by storing information indicating a bank and a segment on which the self refresh operation is not performed; and a mask operation circuit configured to not perform the self refresh operation on the segments of each of the banks in response to the mask information. The semiconductor memory device efficiently performs a refresh operation according to user convenience and supports lower power consumption.

### CROSS-REFERENCE TO RELATED APPLICATIONS

This application claims the benefit of U.S. Provisional Patent Application No. 61/549,836, filed on Oct. 21, 2011, in the U.S. Patent and Trademark Office, and the benefit of Korean Patent Application No. 10-2012-0021406, filed on Feb. 29, 2012, in the Korean Intellectual Property Office, the disclosures of which are incorporated herein in their entirety by reference.

### BACKGROUND

Example embodiments of the inventive concepts relate to semiconductor memory devices, and more particularly, to a semiconductor memory device configured to perform a comprehensive partial self refresh (CPSR) operation of regularly or selectively masking segments included in a bank in a self refresh operation.

As is widely known, Dynamic Random Access Memory (DRAM), which is a representative semiconductor memory device, requires a periodic refresh operation to maintain data stored in memory cells of the DRAM. Refresh operations are classified into auto refresh operations and self refresh operations. If DRAMs are used in mobile application products, low power consumption is strongly desirable. Therefore, a partial array self refresh operation is supported.

### SUMMARY

Some example embodiments of the inventive concepts provide a semiconductor memory device configured to perform a comprehensive partial self refresh (CPSR) operation of regularly or selectively masking segments included in banks in a self refresh operation, and/or a memory system including the semiconductor memory device.

According to an aspect of the inventive concepts, there is provided a semiconductor memory device performing a self refresh operation, the semiconductor memory device including a memory cell array including a plurality of banks each including a plurality of segments; a mask information register configured to generate mask information by storing refresh information indicating a portion of the memory cell array on which the self refresh operation is not performed; and a mask operation circuit configured to not perform the self refresh operation on the portion of the memory cell array in response to the mask information.

Bank information may be set so that the refresh information includes bank information indicating that the self refresh operation is not performed on a bank corresponding to the bank information.

Segment information may be set so that the refresh information includes segment information indicating the self refresh operation is not performed on specific segments in all of the banks, the specific segments being the same for all of the banks.

Segment information may be set so that the refresh information includes segment information indicating that the self refresh operation is not performed on selected segments in specific banks, at least one of the specific banks having at least one selected segment different from another of the specific banks.

The mask information register may include a bank mask information register configured to store bank information indicating the bank on which the self refresh operation is not performed; a first segment mask information register configured to store first segment information indicating specific segments in all banks on which the self refresh operation is not performed; and a second segment mask information register configured to store second segment information indicating selected segments in specific banks on which the self refresh operation is not performed.

The bank information and the segment information may be provided from a mode register configured to allocate a received command address signal to the mask information register.

The semiconductor memory device may further comprise: a self refresh internal command generator configured to periodically generate an internal refresh signal in response to a self refresh command; and an address counter configured to update a refresh address signal in response to the internal refresh signal.

The mask operation circuit may detect a match or a mismatch between the refresh address signal and the mask information in response to the internal refresh signal to generate a match signal.

The match signal may be provided to a switch unit that masks a bank signal or a segment signal corresponding to the refresh address signal.

According to another aspect of the inventive concepts, there is provided a method of refreshing a semiconductor memory device including a plurality of banks each including a plurality of segments, the method including storing bank information and segment information indicating a bank and a segment on which a self refresh operation is not performed; not performing the self refresh operation on a bank corresponding to the bank information, regardless of the segment information; and not performing the self refresh operation on selected segments in specific banks that are different from each other, according to the segment information.

The self refresh operation may not be performed on specific segments of all banks that are the same as each other, according to the segment information.

The bank information and the segment information may be set with values allocated to command address signals loaded at rising edges of a clock signal and loaded at falling edges of the clock signal according to a mode register setting command.

The method may further comprise: periodically generating an internal refresh signal in response to a self refresh command; and updating a refresh address signal in response to the internal refresh signal.

The method may further comprise detecting a match or a mismatch between the refresh address signal and the bank information or the segment information in response to the internal refresh signal to generate a match signal.

The method may further comprise masking a bank signal or a segment signal corresponding to the refresh address signal according to the match signal.

According to an example embodiment, there is provided a semiconductor memory device performing a self refresh operation, the semiconductor memory device including a memory cell array including a plurality of banks, each bank including a plurality of segments and control logic configured to not perform the self refresh operation on selected segments in selected banks of the memory cell array.

The control logic may be configured to set bank information indicating the selected banks.

The control logic may be configured to set segment information indicating the selected segments, the segment information indicating the selected segments in all of the banks, the selected segments being the same for all of the banks.

The control logic may be configured to set segment information indicating the selected segments, the segment information indicating the selected segments in the selected banks, at least one of the selected banks having at least one selected segment different from another of the specific banks.

The control logic may include a bank mask information register configured to store bank information indicating the selected banks on which the self refresh operation is not performed; a first segment mask information register configured to store first segment information indicating first specific segments in all banks on which the self refresh operation is not performed; and a second segment mask information register configured to store second segment information indicating second specific segments in the selected banks on which the self refresh operation is not performed.

### BRIEF DESCRIPTION OF THE DRAWINGS

Example embodiments of the inventive concepts will be more clearly understood from the following detailed description taken in conjunction with the accompanying drawings in which:

FIG. 1 is a block diagram of a semiconductor memory device that performs comprehensive partial self refresh (CPSR) operations according to various example embodiments of the inventive concepts;

FIG. 2 illustrates an example of a structure of a memory cell array included in the semiconductor memory device illustrated in FIG. 1;

FIG. 3 illustrates an example of allocation of command address signals CA0-CA9 for setting a mode register;

FIG. 4 illustrates an example of a method of inputting setting signals MR16, MR17, and MR64-MR71;

FIG. 5 is an example of a table showing a relationship between signals OP0-OP7 and banks to be masked;

FIG. 6 is an example of a table showing a relationship between signals OP0-OP7 and banks to be masked;

FIGS. 7 and 8 are diagrams for explaining banks and segments to be masked by mask information according to an example embodiment of the inventive concepts;

FIGS. 9 and 10 are diagrams for explaining banks and segments to be masked by mask information according to another example embodiment of the inventive concepts;

FIG. 11 is an example of a circuit diagram of a mask operation circuit included in the semiconductor memory device illustrated in FIG. 1;

FIG. 12 is an example of a diagram for explaining a method of masking banks or segments according to a match signal;

FIGS. 13 and 14 are timing charts for explaining CPSR operations according to various example embodiments of the inventive concepts;

FIG. 15 is an example of a diagram for explaining banks and segments that are masked according to the timing chart of FIG. 14;

FIG. 16 is a block diagram of a memory system to which the semiconductor memory device of FIG. 1 is applied, according to an example embodiment of the inventive concepts; and

FIG. 17 is a block diagram of a computing system on which a memory system is mounted, according to an example embodiment of the inventive concepts.

### DETAILED DESCRIPTION OF EXAMPLE EMBODIMENTS

Hereinafter, example embodiments of the inventive concepts will be described more fully with reference to the accompanying drawings, in which some example embodiments of the inventive concepts are shown. These example embodiments are provided so that this disclosure will be thorough and complete, and will fully convey the scope of the inventive concepts to one of ordinary skill in the art. As the inventive concepts allow for various changes and numerous embodiments, particular example embodiments will be illustrated in the drawings and described in detail in the written description. However, this is not intended to limit example embodiments of the inventive concepts to particular modes of practice, and it is to be appreciated that all changes, equivalents, and substitutes that do not depart from the spirit and technical scope of the example embodiments of the inventive concepts are encompassed. In the drawings, like reference numerals denote like elements and the sizes or thicknesses of elements may be exaggerated for clarity of explanation.

The terms used in the present specification are merely used to describe particular example embodiments, and are not intended to limit all example embodiments of the inventive concepts. An expression used in the singular encompasses the expression in the plural, unless it has a clearly different meaning in the context. In the present specification, it is to be understood that the terms such as “including,” “comprising” or “having,” etc., are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

Unless defined differently, all terms used in the description including technical and scientific terms have the same meaning as generally understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. Expressions such as “at least one of,” when preceding a list of elements, modify the entire list of elements and do not modify the individual elements of the list.

Dynamic Random Access Memory (DRAM) requires a periodic refresh operation to maintain data stored in memory cells of the DRAM. Refresh operations are classified into auto refresh operations and self refresh operations. An auto refresh operation is performed every time a refresh command is issued from outside, and a self refresh operation is performed according to a refresh signal that is internally generated in a periodic and automatic manner. The self refresh operation is performed at the time of standby in order to reduce power consumption. A partial array self refresh operation is not performed on the whole memory cell array, but is performed only on desired areas. If a partial array self refresh operation is performed, because a refresh operation is omitted for areas in which data does not need to be maintained, power consumption may be reduced.

It may be determined whether to perform a refresh operation on a desired memory cell array area in a partial array self refresh operation, according to a desired pattern prepared in advance. For example, in a memory composed of banks 0 to 7, a refresh operation for each of the banks 0 to 7 may include 255 (=2 8−1) patterns. “1” may be subtracted from “2 8” because a pattern of performing a partial array self refresh operation on none of the banks is excluded.

In recent years, it is desirable to divide each of the banks into a plurality of segments and to specify a refresh operation for each of the segments. Assuming a memory configuration of 8 banks×8 segments, because a refresh operation includes 255 (=2 8−1) patterns for the 8 banks and 255 (=2 8−1) patterns for the 8 segments, the total number of patterns becomes 65025 (=255 2).

As a result, it takes an unrealistic length of time to perform a refresh operation for the entire patterns. To address this problem, a comprehensive partial self refresh (CPSR) operation of regularly blocking a refresh operation from being performed on specific banks and specific segments is desirable. In addition, a CPSR operation of selectively blocking a refresh operation from being performed on specific banks and selected segments is desirable. In the CPSR operation, a refresh operation on a segment in a bank in which data does not need to be maintained may be selectively blocked according to user convenience. Accordingly, the CPSR operation may support low power consumption.

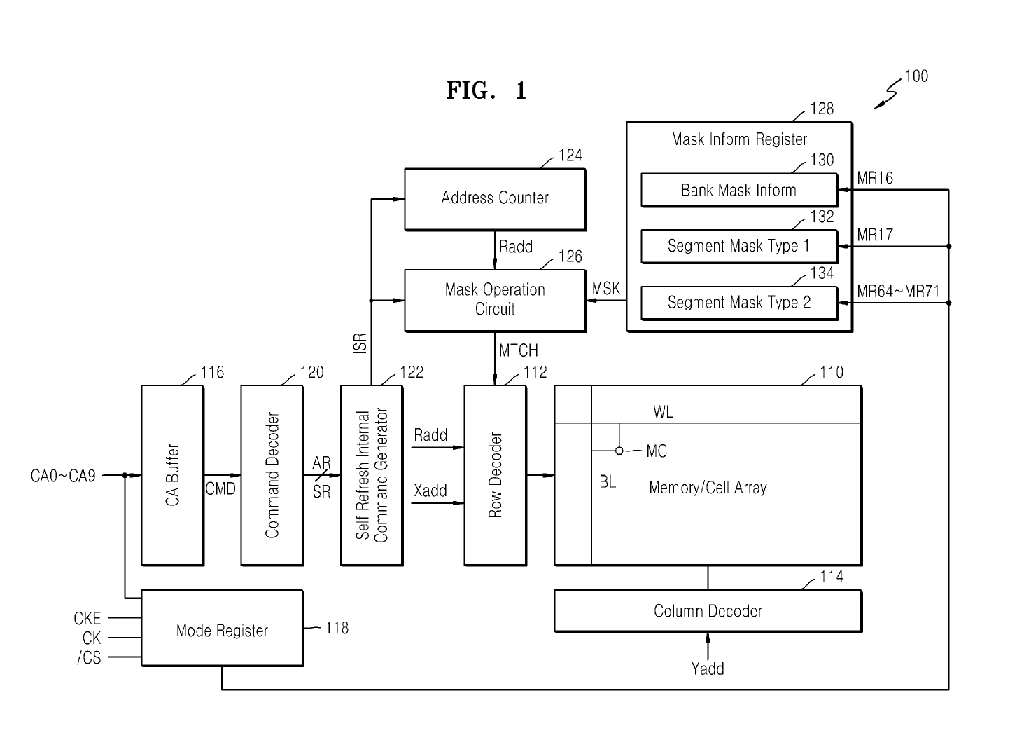

FIG. 1 is a block diagram of a semiconductor memory device 100 that performs CPSR operations according to various example embodiments of the inventive concepts.

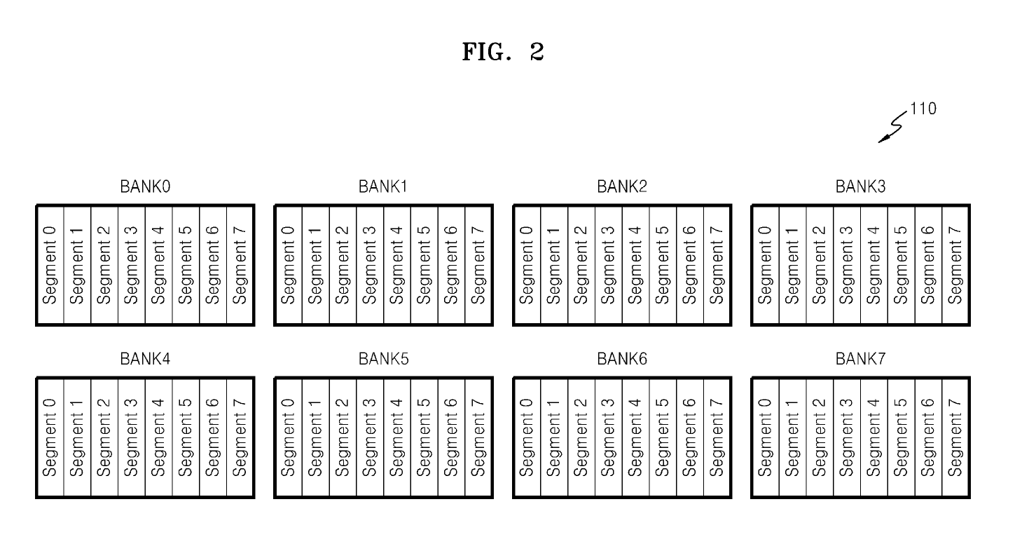

Referring to FIG. 1, the semiconductor memory device 100 includes a memory cell array 110 including a plurality of DRAM memory cells MC. In the memory cell array 110, a plurality of word lines WL intersect with a plurality of bit lines BL, and a memory cell MC is arranged at an intersection of each word line WL and each bit line BL. As illustrated in FIG. 2, the memory cell array 110 may be divided into 8 banks including zeroth to seventh banks BANK0-BANK7, each of which may be divided into 8 segments including zeroth to seventh segments Segment0-Segment7.

A word line WL included in the memory cell array 110 may be selected by a row decoder 112. The row decoder 112 may decode a signal corresponding to a row address Xadd from command address signals CA0-CA9 to generate a row selection signal (not shown). The row decoder 112 may select a word line WL in response to the row selection signal. The row decoder 112 may select a word line WL in response to a refresh address signal Radd.

A bit line BL included in the memory cell array 110 may be selected by a column decoder 114. The column decoder 114 may decode a signal corresponding to a column address Yadd from the command address signals CA0-CA9 to generate a column selection signal (not shown). The column decoder 114 may select a bit line BL in response to the column selection signal.

The command address signals CA0-CA9 may be provided to a command address buffer 116. The command address buffer 116 may receive the command address signals CA0-CA9 and latch the command address signals CA0-CA9 separately as a command signal CMD and the row and column addresses Xadd and Yadd. The command signal CMD may be provided to a command decoder 120. The command decoder 120 may generate a self refresh command SR and an auto refresh command AR based on the received command signal CMD.

The self refresh command SR may be provided to a self refresh address internal command generator 122. If the self refresh command SR is activated, the self refresh address internal command generator 122 may periodically generate an internal refresh signal ISR. The internal refresh signal ISR may be provided to an address counter 124 and a mask operation circuit 126.

The address counter 124 may generate a refresh address signal Radd in response to the internal refresh signal ISR. A count value of the address counter 124 may be updated in response to the internal refresh signal ISR. The refresh address signal Radd may be provided to the mask operation circuit 126 and the row decoder 112.

The mask operation circuit 126 may detect a match or a mismatch between the refresh address signal Radd and mask information MSK in response to the internal refresh signal ISR and may generate a match signal MTCH. The mask information MSK is provided from a mask information register 128 and indicates a bank and a segment on which a self refresh operation is not performed from among the banks and segments included in the memory cell array 110.

The mask information register 128 may include a bank mask information register 130, a first segment mask information register 132, and a second segment mask information register 134. The bank mask information register 130 may store information indicating a bank on which the self refresh operation is not performed. The first and second segment mask information registers 132 and 134 may store information indicating a segment on which the self refresh operation is not performed. Segment information stored in the first segment mask information register 132 blocks a refresh operation from being performed with respect to a specific segment in each bank. Segment information stored in the second segment mask information register 134 blocks a refresh operation from being performed with respect to an selected segment in each bank.

According to the present example embodiment, the mask information register 128 stores information indicating a bank or a segment on which the self refresh operation is not performed. Alternatively, the mask information register 128 may store information indicating a bank or a segment on which the self refresh operation is performed.

The mask information register 128 may generate the mask information MSK according to setting signals provided from a mode register 118. The mode register 118 may provide, for example, setting signals MR16, MR17, and MR64-MR71, to the mask information register 128. The mode register 118 may receive and allocate the command address signals CA0-CA9 to generate the setting signals MR16, MR17, and MR64-MR71.

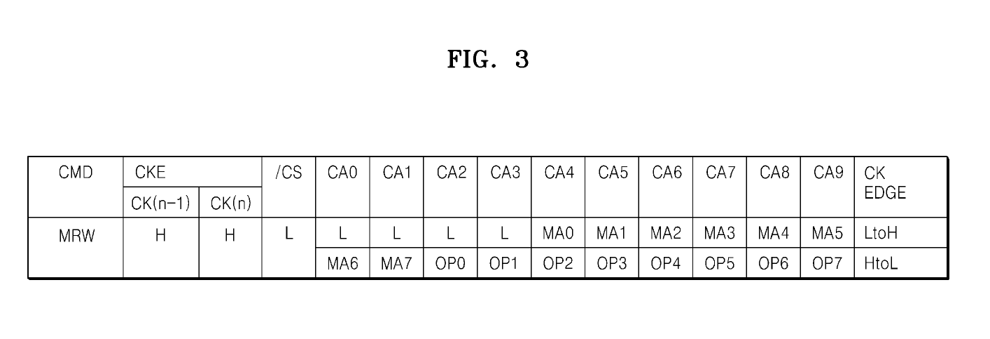

FIG. 3 illustrates an example of an allocation of the command address signals CA0-CA9 for setting the mode register 118.

Referring to FIG. 3, according to a mode register setting command MRW, each of the command address signals CA0-CA9 may be loaded at a rising edge and a falling edge of a clock signal CK. The command address signals CA4-CA9 that are loaded at the rising edges of the clock signal CK and the command address signals CA0 and CA1 that are loaded at the falling edges of the clock signal CK may be used as signals MA0-MA7, respectively. The command address signals CA2-CA9 that are loaded at the falling edges of the clock signal CK may be used as signals OP0-OP7, respectively. The signals MA0-MA7 and the signals OP0-OP7 may be used as the setting signals MR16, MR17, and MR64-MR71.

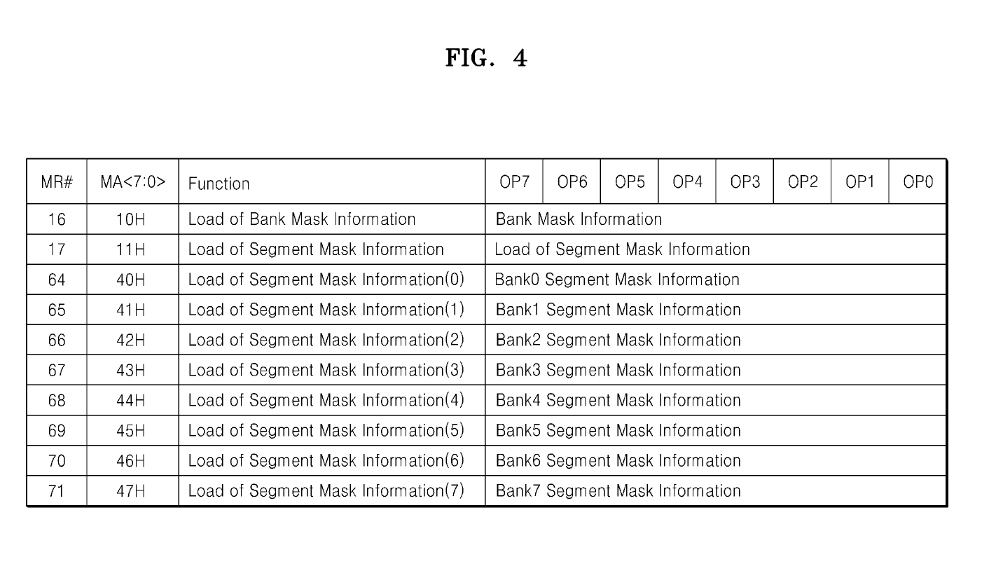

FIG. 4 illustrates an example of a method of inputting the setting signals MR16, MR17, and MR64-MR71.

Referring to FIG. 4, if values of the signals MA0-MA7 indicate 10H (hexadecimal value), the method enters an input mode for the setting signal MR16, and values of the signals OP0-OP7 may be used as bank mask information. If the values of the signals MA0-MA7 indicate 11H (hexadecimal value), the method enters an input mode for the setting signal MR17, and the values of the signals OP0-OP7 may be used as segment mask information.

If the values of the signals MA0-MA7 indicate 40H (hexadecimal value), the method enters an input mode for the setting signal MR64, and the values of the signals OP0-OP7 may be used as BANK0 segment mask information. If the values of the signals MA0-MA7 indicate 41H (hexadecimal value), the method enters an input mode for the setting signal MR65, and the values of the signals OP0-OP7 may be used as BANK1 segment mask information. If the values of the signals MA0-MA7 indicate 42H (hexadecimal value), the method enters an input mode for the setting signal MR66, and the values of the signals OP0-OP7 may be used as segment mask information of the bank BANK2. If the values of the signals MA0-MA7 indicate 43H (hexadecimal value), the method enters an input mode for the setting signal MR67, and the values of the signals OP0-OP7 may be used as segment mask information of the bank BANK3.

If the values of the signals MA0-MA7 indicate 44H (hexadecimal value), the method enters an input mode for the setting signal MR68, and the values of the signals OP0-OP7 may be used as segment mask information of the bank BANK4. If the values of the signals MA0-MA7 indicate 45H (hexadecimal value), the method enters an input mode for the setting signal MR69, and the values of the signals OP0-OP7 may be used as segment mask information of the bank BANK5. If the values of the signals MA0-MA7 indicate 46H (hexadecimal value), the method enters an input mode for the setting signal MR70, and the values of the signals OP0-OP7 may be used as segment mask information of the bank BANK6. If the values of the signals MA0-MA7 indicate 47H (hexadecimal value), the method enters an input mode for the setting signal MR71, and the values of the signals OP0-OP7 may be used as segment mask information of the bank BANK7.

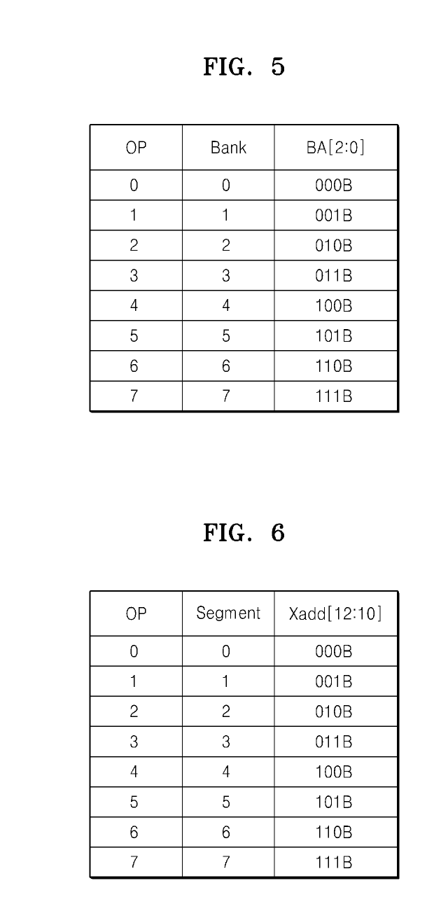

FIG. 5 is an example of a table showing a relationship between the signals OP0-OP7 and banks to be masked.

Referring to FIG. 5, if the bank mask information is set, the signals OP0-OP7 may be allocated to banks 0-7, respectively. If logical values of the allocated signals OP0-OP7 are “0”, banks corresponding to the signals OP0-OP7 may be set to a non-mask state in which the self refresh operation is enabled. If the logical values of the allocated signals OP0-OP7 are “1”, the banks corresponding to the signals OP0-OP7 may be set to a mask state in which the self refresh operation is disabled.

The banks BANK0-BANK7 may be specified by bank addresses BA[2:0]. If the bank addresses BA[2:0] are 000b (binary number), it may indicate a BANK0 bank signal, and if the bank addresses BA[2:0] are 001b (binary number), it may indicate a BANK1 bank signal. If the bank addresses BA[2:0] are 010b, 011b, 100b, 101b, 110b, and 111b (binary number), they may indicate BANK2, BANK3, BANK4, BANK5, BANK6, and BANK7 bank signals.

FIG. 6 is an example of a table showing a relationship between the signals OP0-OP7 and banks to be masked.

Referring to FIG. 6, if the bank mask information is set, the signals OP0-OP7 may be allocated to segments 0-7, respectively. If the logical values of the allocated signals OP0-OP7 are “0”, segments corresponding to the signals OP0-OP7 may be set to a non-mask state in which the self refresh operation is enabled. If the logical values of the allocated signals OP0-OP7 are “1”, the segments corresponding to the signals OP0-OP7 may be set to a mask state in which the self refresh operation is disabled.

The segments may be specified by high bits of row addresses Xadd[12:10]. The banks BANK0-BANK7 may be specified by the bank addresses BA[2:0]. If the row addresses Xadd[12:10] are 000b (binary number), it may indicate a Segment0 segment signal, and if the row addresses Xadd[12:10] are 001b (binary number), it may indicate a Segment1 segment signal. If the row addresses Xadd[12:10] are 010b, 011b, 100b, 101b, 110b, and 111b (binary number), they may indicate Segment2, Segment3, Segment4, Segment5, Segment6, and Segment7 segment signals.

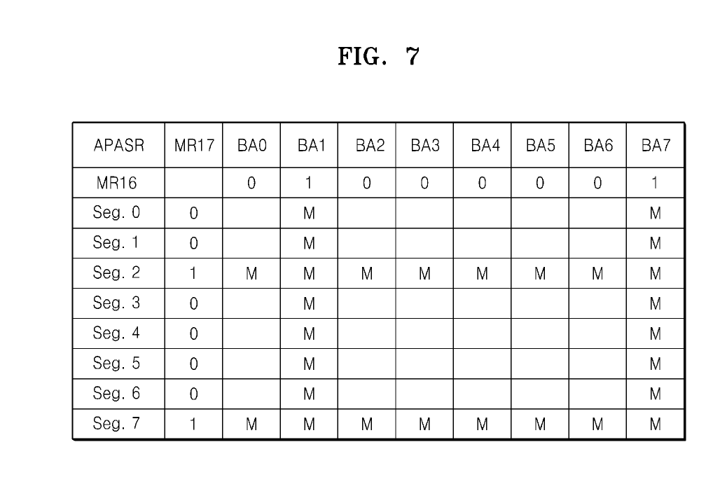

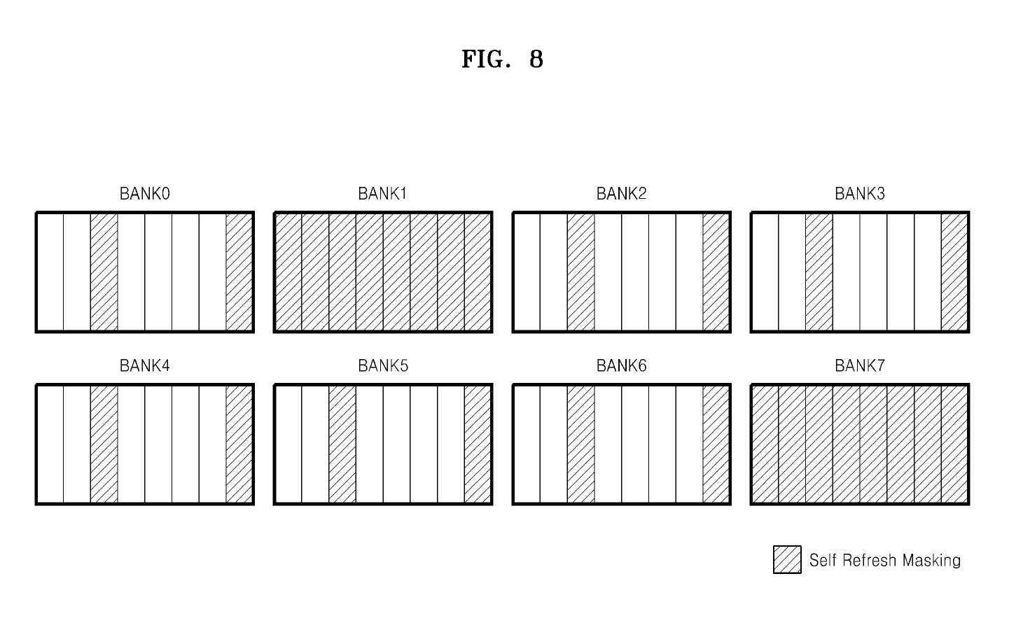

FIGS. 7 and 8 are diagrams for explaining banks and segments to be masked by the mask information MSK according to an example embodiment of the inventive concepts.

In the table of FIG. 7, portions filled in with “M” are the banks and the segments to be masked. If bank mask information set in an MR16 mode register is 10000010b (binary number), the banks BANK1 and BANK7 may be masked. If segment mask information set in an MR17 mode register is 10000100b (binary number), the segments Segment2 and Segment7 may be masked. Accordingly, as illustrated in FIG. 8, the self refresh operation may not be performed on the masked banks BANK1 and BANK7, and the self refresh operation may not be performed on the masked segments Segment2 and Segment7 of the banks BANK0 and BANK2-BANK6. In other words, specific segments in banks that are the same as each other may be masked.

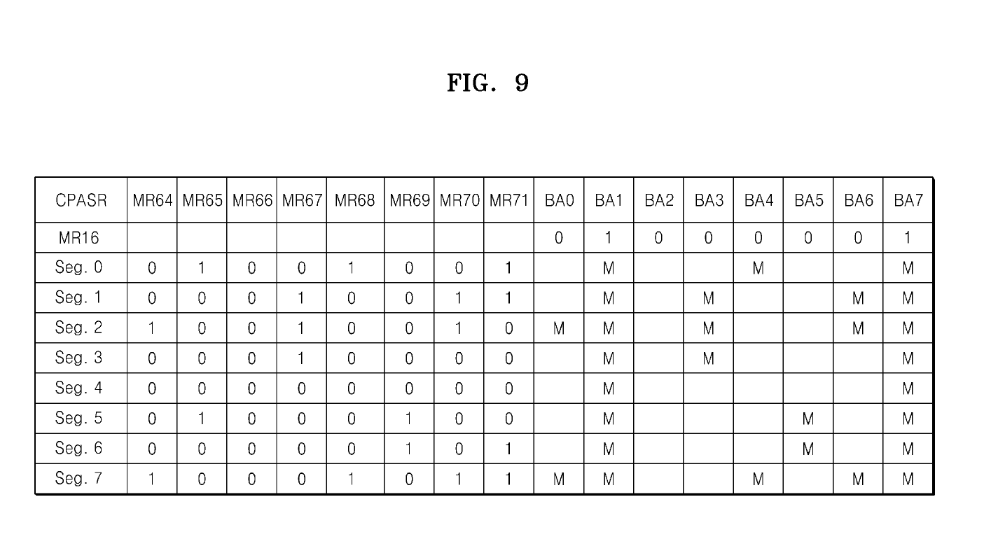

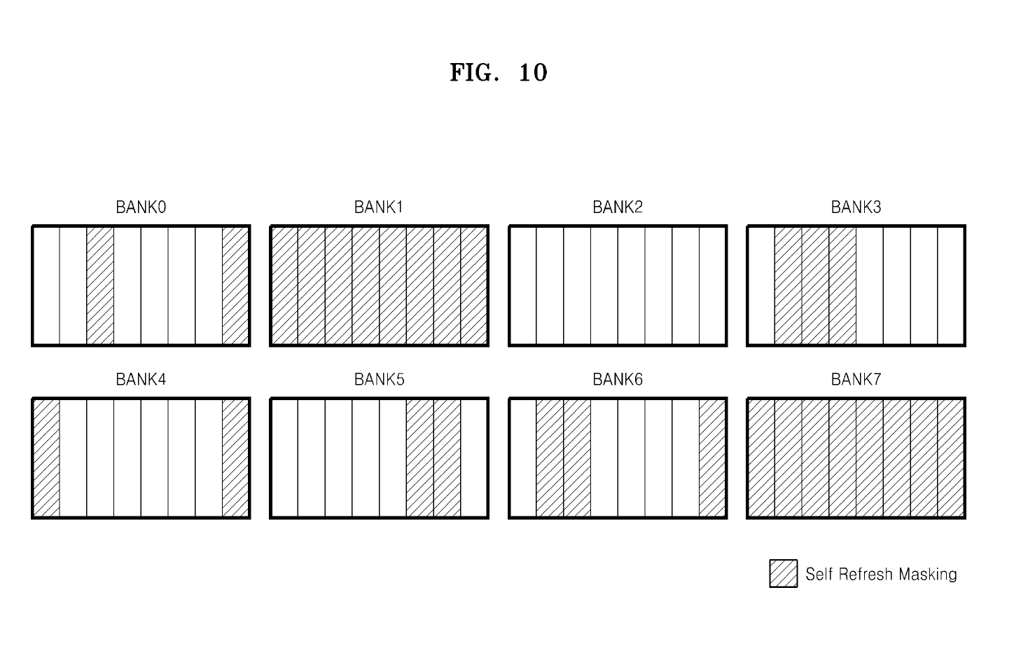

FIGS. 9 and 10 are diagrams for explaining banks and segments to be masked by the mask information MSK according to another example embodiment of the inventive concepts.

Referring to FIG. 9, if bank mask information set in an MR16 mode register is 10000010b (binary number), the banks BANK1 and BANK7 may be masked. If segment mask information set in an MR64 mode register is 10000100b (binary number), the segments Segment2 and Segment7 of the bank BANK0 may be masked. If segment mask information set in an MR65 mode register is 00100001b (binary number), the segments Segment2 and Segment7 of the bank BANK1 may be masked.

If segment mask information set in an MR66 mode register is 00000000b (binary number), none of the segments of the bank BANK2 may be masked, and a self refresh operation is performed on the segments. If segment mask information set in an MR67 mode register is 00001110b (binary number), the segments Segment1, Segment 2, and Segment3 of the bank BANK3 may be masked. If segment mask information set in an MR68 mode register is 10000001b (binary number), the segments Segment0 and Segment7 of the bank BANK4 may be masked.

If segment mask information set in an MR69 mode register is 01100000b (binary number), the segments Segment5 and Segment6 of the bank BANK5 may be masked. If segment mask information set in an MR70 mode register is 10000110b (binary number), the segments Segment1, Segment2, and Segment7 of the bank BANK6 may be masked. If segment mask information set in an MR71 mode register is 10000110b (binary number), the segments Segment0, Segment1, Segment 6, and Segment7 of the bank BANK7 may be masked.

Referring to FIG. 10, the banks BANK1 and BANK7 are masked, and a self refresh operation is not performed thereon, Segment2 and Segment7 of the bank BANK0 are masked and the self refresh operation is not performed thereon, Segment1, Segment2, and Segment3 of the bank BANK3 are masked and the self refresh operation is not performed thereon, Segment0 and Segment7 of the bank BANK4 are masked and the self refresh operation is not performed thereon, Segment5 and Segment6 of the bank BANK5 are masked and the self refresh operation is not performed thereon, and Segment 1, Segment2, and Segment7 of the bank BANK6 are masked and the self refresh operation is not performed thereon. In other words, selected segments in banks that are different from each other may be masked.

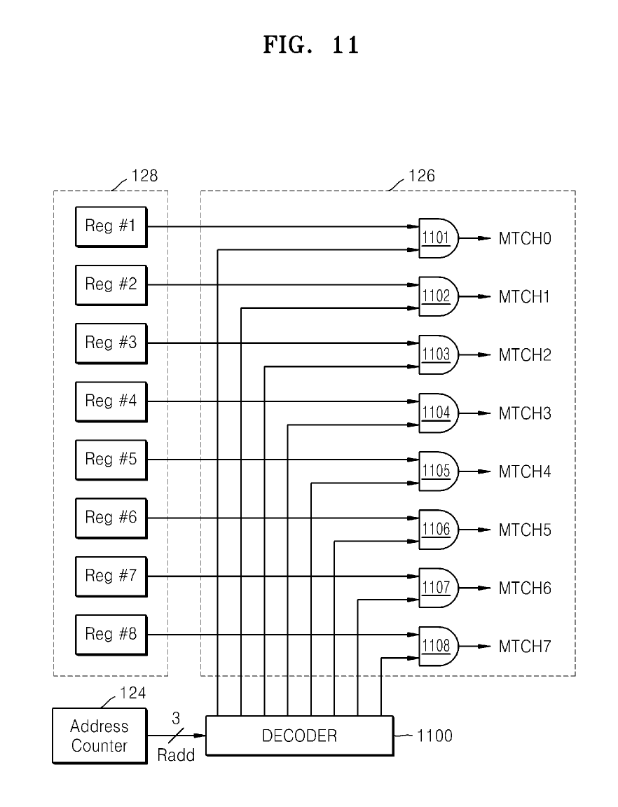

FIG. 11 is an example of a circuit diagram of the mask operation circuit 126 of FIG. 1.

Referring to FIG. 11, the mask operation circuit 126 may receive the mask information MSK from the mask information register 128. The mask information MSK may be provided as output signals of first to eighth registers REG1 to REG8 for storing the signals OP0-OP7, respectively. The output signals of the first to eighth registers REG1 to REG8 may be information indicating banks or segments to be masked.

The mask operation circuit 126 may receive output signals of a decoder 1100 for decoding the refresh address signal Radd from the address counter 124. The refresh address signal Radd may be provided as the bank addresses BA[2:0] or the row addresses Xadd[12:10]. The decoder 1100 may decode the bank addresses BA[2:0] to generate bank signals on which the self refresh operation is performed, or decode the row addresses Xadd[12:10] to generate segment signals on which the self refresh operation is performed.

The mask operation circuit 126 may include gate circuits, namely, first to eighth AND gates 1101 to 1108, which perform AND operations on bank mask signals stored in the first to eighth registers REG1 to REG8 and the bank signals output from the decoder 1100.

The first AND gate 1101 may output a match signal MTCH0 if the signal OP0 stored in the first register REG1 matches a BANK0 bank signal. The second AND gate 1102 may output a match signal MTCH1 if the signal OP1 stored in the second register REG2 matches a BANK1 bank signal. Similarly, the third to eighth AND gates 1103-1108 may output match signals MTCH2-MTCH7 if the signals OP2-OP7 respectively stored in the third to eighth registers REG3-REG8 match BANK2-BANK7 bank signals, respectively.

The mask operation circuit 126 may include the gate circuits, namely, the first to eighth AND gates 1101 to 1108, which perform AND operations on segment mask signals stored in the first to eighth registers REG1 to REG8 and the segment signals output from the decoder 1100. The first AND gate 1101 may output a match signal MTCH0 if the signal OP0 stored in the first register REG1 matches a Segment0 segment signal. The second AND gate 1102 may output a match signal MTCH1 if the signal OP1 stored in the second register REG2 matches a Segment2 segment signal. Similarly, the third to eighth AND gates 1103-1108 may output match signals MTCH2-MTCH7 if the signals OP2-OP7 respectively stored in the third to eighth registers REG3-REG8 match Segment2 to Segment7 segment signals, respectively.

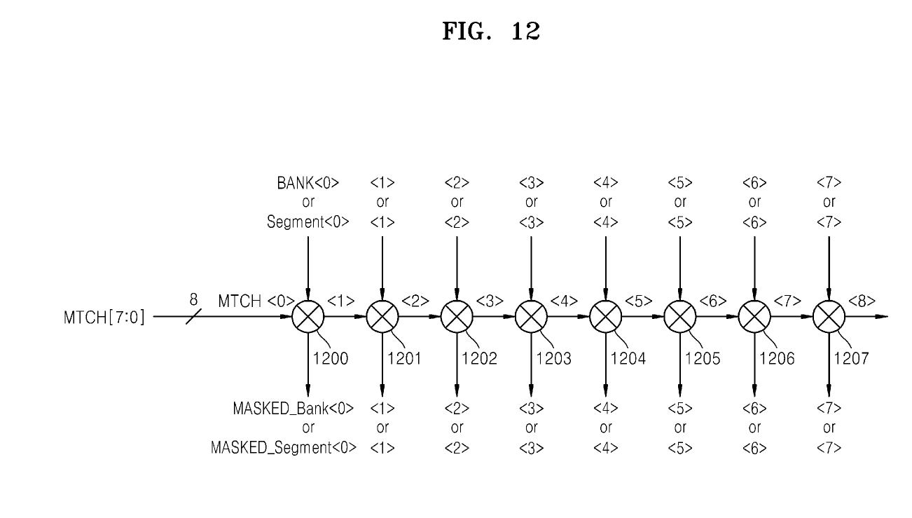

FIG. 12 is an example of a diagram for explaining a method of masking banks or segments according to a match signal MTCH.

Referring to FIG. 12, match signals MTCH[7:0] may be provided to first to eighth switches 1200-1207 for masking BANK0-BANK7 bank signals, respectively. The first to eighth switches 1200-1207 may be included in the mask operation circuit 126 or the row decoder 112. The first switch 1200 may mask a BANK0 bank signal in response to an activation of the match signal MTCH0 to generate a masked BANK0 bank signal. The second switch 1201 may mask a BANK1 bank signal in response to an activation of the match signal MTCH1 to generate a masked BANK1 bank signal. Similarly, the third to eighth switches 1202-1277 may mask BANK0 to BANK7 bank signals in response to activations of the match signals MTCH0 to MTCH7 to generate masked BANK2 to BANK7 bank signals.

The match signals MTCH[7:0] may be provided to the first to eighth switches 1200-1207 for masking Segment0 to Segment7 segment signals, respectively. The first switch 1200 may mask a Segment0 segment signal in response to an activation of the match signal MTCH0 to generate a masked Segment0 segment signal. The second switch 1201 may mask a Segment1 segment signal in response to an activation of the match signal MTCH1 to generate a masked Segment 1 segment signal. Similarly, the third to eighth switches 1202-1277 may mask Segment2 to Segment7 segment signals in response to activations of the match signals MTCH0 to MTCH7 to generate masked Segment2 to Segment7 segment signals.

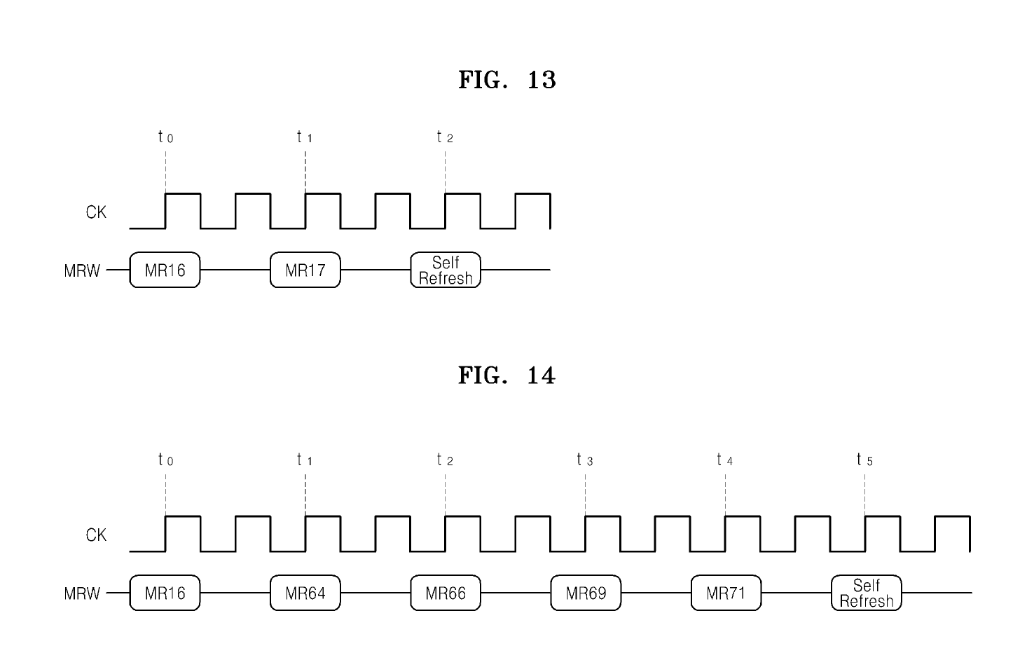

FIGS. 13 and 14 are timing charts for explaining CPSR operations according to various example embodiments of the inventive concepts.

Referring to FIG. 13, according to the mode register setting command MRW, the MR16 mode register may be set at a timing t0 of the clock signal CK. The command address signals CA4-CA9 loaded at the rising edges of the clock signal CK and the command address signals CA0 and CA1 loaded at the falling edges of the clock signal CK may be input as the signals MA0-MA7, respectively, and values of the signals MA0-MA7 may be set to 10H (hexadecimal value). The command address signals CA2-CA9 that are loaded at the falling edges of the clock signal CK may be input as the signals OP0-OP7, respectively, and values of the signals OP0-OP7 may be set to bank mask information.

At a timing t1 of the clock signal CK, the MR17 mode register may be set. The command address signals CA4-CA9 loaded at the rising edges of the clock signal CK and the command address signals CA0 and CA1 loaded at the falling edges of the clock signal CK may be input as the signals MA0-MA7, respectively, and the values of the signals MA0-MA7 may be set to 11H (hexadecimal value). The command address signals CA2-CA9 that are loaded at the falling edges of the clock signal CK may be input as the signals OP0-OP7, respectively, and the values of the signals OP0-OP7 may be set to regular segment mask information of all banks.

At a timing t2 of the clock signal CK, a self refresh operation may be performed according to the bank mask information set in the MR16 mode register and the segment mask information set in the MR17 mode register. As described above with reference to FIG. 7, if the bank mask information set in the MR16 mode register is 10000010b (binary number) and the segment mask information set in the MR17 mode register is 10000100b (binary number), the self refresh operation is not performed on the banks BANK1 and BANK7 and the self refresh operation is not performed on the Segment2 and Segment7 of the banks BANK0 and BANK3-BANK6, as illustrated in FIG. 8.

Referring to FIG. 14, according to the mode register setting command MRW, the MR16 mode register may be set at a timing t0 of the clock signal CK. The command address signals CA4-CA9 loaded at the rising edges of the clock signal CK and the command address signals CA0 and CA1 loaded at the falling edges of the clock signal CK may be input as the signals MA0-MA7, respectively, and values of the signals MA0-MA7 may be set to 10H (hexadecimal value). The command address signals CA2-CA9 that are loaded at the falling edges of the clock signal CK may be input as the signals OP0-OP7, respectively, and values of the signals OP0-OP7 may be set to bank mask information.

At a timing t1 of the clock signal CK, the MR64 mode register may be set. The command address signals CA4-CA9 loaded at the rising edges of the clock signal CK and the command address signals CA0 and CA1 loaded at the falling edges of the clock signal CK may be input as the signals MA0-MA7, respectively, and the values of the signals MA0-MA7 may be set to 40H (hexadecimal value). The command address signals CA2-CA9 that are loaded at the falling edges of the clock signal CK may be input as the signals OP0-OP7, respectively, and values of the signals OP0-OP7 may be set to segment mask information of the bank BANK0.

At a timing t2 of the clock signal CK, the MR66 mode register may be set. The command address signals CA4-CA9 loaded at the rising edges of the clock signal CK and the command address signals CA0 and CA1 loaded at the falling edges of the clock signal CK may be input as the signals MA0-MA7, respectively, and the values of the signals MA0-MA7 may be set to 42H (hexadecimal value). The command address signals CA2-CA9 that are loaded at the falling edges of the clock signal CK may be input as the signals OP0-OP7, respectively, and values of the signals OP0-OP7 may be set to segment mask information of the bank BANK2.

At a timing t3 of the clock signal CK, the MR69 mode register may be set. The command address signals CA4-CA9 loaded at the rising edges of the clock signal CK and the command address signals CA0 and CA1 loaded at the falling edges of the clock signal CK may be input as the signals MA0-MA7, respectively, and the values of the signals MA0-MA7 may be set to 45H (hexadecimal value). The command address signals CA2-CA9 that are loaded at the falling edges of the clock signal CK may be input as the signals OP0-OP7, respectively, and values of the signals OP0-OP7 may be set to segment mask information of the bank BANK5.

At a timing t4 of the clock signal CK, the MR71 mode register may be set. The command address signals CA4-CA9 loaded at the rising edges of the clock signal CK and the command address signals CA0 and CA1 loaded at the falling edges of the clock signal CK may be input as the signals MA0-MA7, respectively, and the values of the signals MA0-MA7 may be set to 47H (hexadecimal value). The command address signals CA2-CA9 that are loaded at the falling edges of the clock signal CK may be input as the signals OP0-OP7, respectively, and values of the signals OP0-OP7 may be set to segment mask information of the bank BANK7.

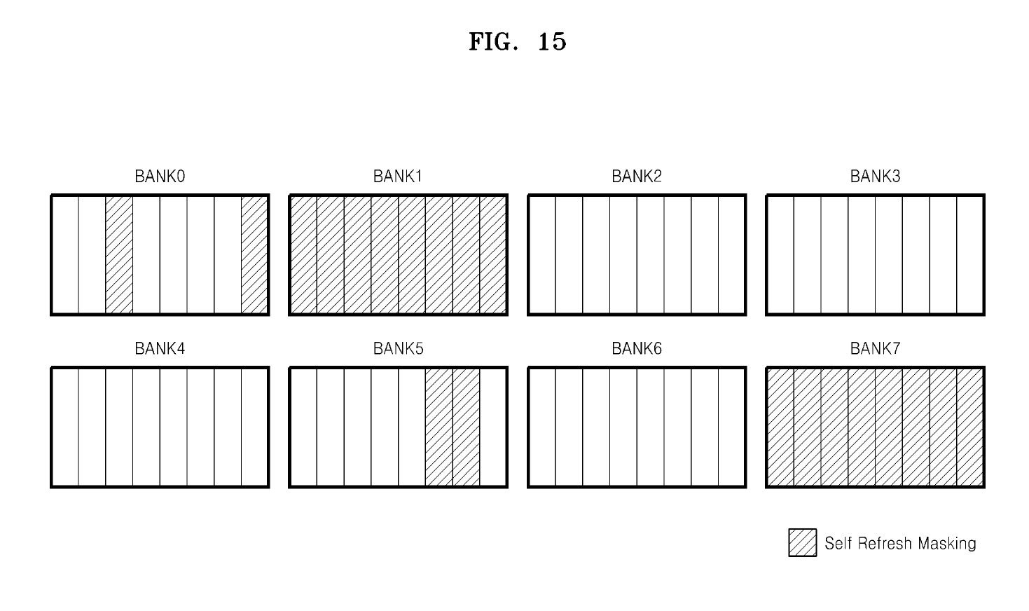

At a timing t5 of the clock signal CK, a self refresh operation may be performed according to the bank mask information set in the MR16 mode register and the segment mask information set in the MR64, MR66, MR69, and MR71 mode registers. As described above with reference to FIG. 9, for example, the bank mask information set in the MR16 mode register may be 10000010b (binary number), the segment mask information set in the MR64 mode register may be 10000100b (binary number), the segment mask information set in the MR66 mode register may be 00000000b (binary number), the segment mask information set in the MR69 mode register may be 01100000b (binary number), and the segment mask information set in the MR71 mode register may be 11000011b. Accordingly, as illustrated in FIG. 15, the self refresh operation may not be performed on the banks BANK1 and BANK7, the self refresh operation may not be performed on the segments Segment2 and Segment7 of the banks BANK0, the self refresh operation may be performed on all of the segments of the bank BANK2, and the self refresh operation may not be performed on the segments Segment5 and Segment6 of the bank BANK5.

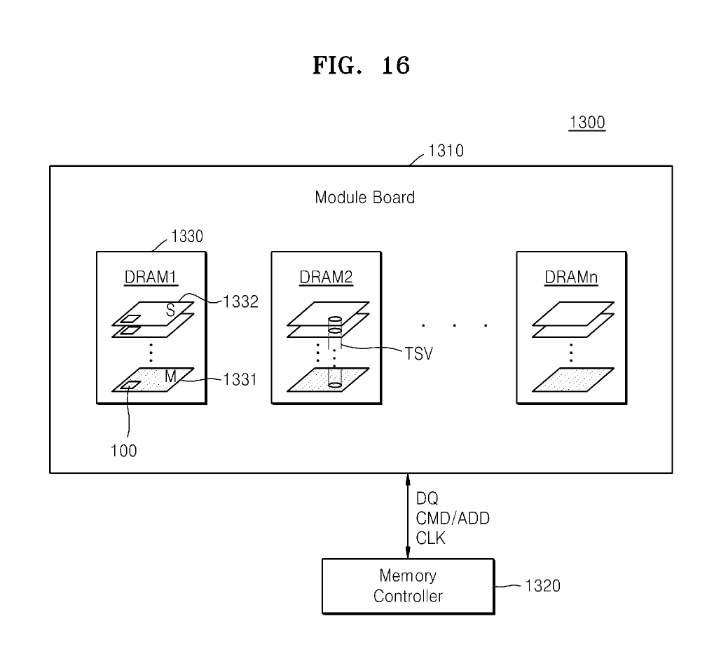

FIG. 16 is a block diagram of a memory system 1300 to which the semiconductor memory device 100 of FIG. 1 is applied, according to an example embodiment of the inventive concepts.

Referring to FIG. 16, the memory system 1300 may include a memory controller 1320 and a memory module 1310. The memory module 1310 may include at least one semiconductor memory device 1330 mounted on a module board. For example, the semiconductor memory device 1330 may be a DRAM chip. The semiconductor memory device 1330 may include a plurality of semiconductor layers. The semiconductor layers may include at least one master chip 1331 and at least one slave chip 1332. Transmission of a signal between the semiconductor layers may be performed via through silicon vias (TSVs).

The master chip 1331 and the slave chip 1332 may perform CPSR operations according to various example embodiments of the inventive concepts. The master chip 1331 and the slave chip 1332 may each include the semiconductor memory device 100 of FIG. 1. The semiconductor memory device 100 may include a memory cell array having a plurality of banks each including a plurality of segments, a mask information register that generates mask information by storing information indicating a bank and a segment on which the self refresh operation is not performed, and a mask operation circuit that does not perform the self refresh operation on segments of each bank in response to the mask information. The bank information may be set so that the self refresh operation is not performed on a corresponding bank, regardless of the segment information. The segment information may be set so that the self refresh operation is not performed on specific segments of all banks that are the same as each other. The segment information may be set so that the self refresh operation is not performed on selected segments of specific banks that are different from each other.

The memory module 1310 may communicate with the memory controller 1320 via a system bus. Data DQ, a command/address CMD/ADD, a clock signal CLK, and the like may be transmitted between the memory module 1310 and the memory controller 1320 via the system bus.

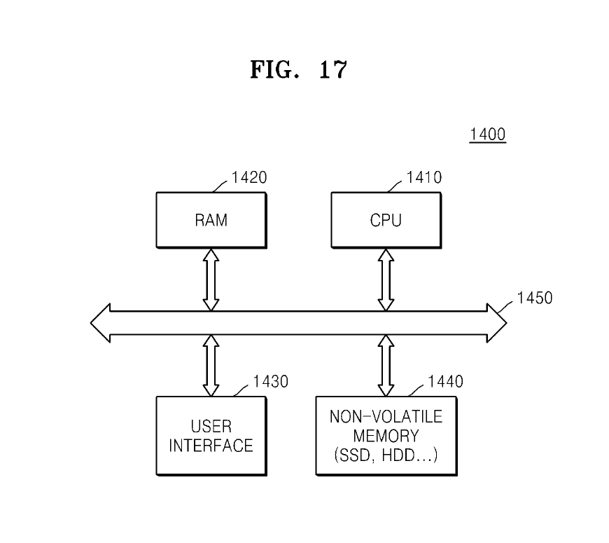

FIG. 17 is a block diagram of a computing system 1400 on which a memory system is mounted, according to an example embodiment of the inventive concepts.

Referring to FIG. 7, a semiconductor memory device according to some example embodiments of the inventive concepts may be mounted as a RAM 1420 in the computing system 1400 such as a mobile device or a desktop computer. The semiconductor memory device mounted as the RAM 1420 may be one of the semiconductor memory devices according to the above-described example embodiments. For example, the RAM 1420 may be a semiconductor memory device according to one of the above-described example embodiments or may be in a memory module form. The RAM 1420 may be a concept including a semiconductor memory device and a memory controller.

Referring to FIG. 17, the computing system 1400 includes a central processing unit (CPU) 1410, the RAM 1420, a user interface 1430, and a non-volatile memory 1440, which are each electrically connected to a bus 1450. The non-volatile memory 1440 may be a large-capacity storage device such as an SSD or an HDD.

In the computing system 1400, the RAM 1420 may perform CPSR operations according to various example embodiments of the inventive concepts. The CPSR operation may include, in a refresh operation on a semiconductor memory device, an operation of storing information indicating a bank and a segment on which a self refresh operation is not performed, an operation of not performing the self refresh operation on a bank corresponding to the bank information regardless of the segment information, and an operation of not performing the self refresh operation on selected segments in specific banks that are different from each other, according to the segment information. In addition, in the CPSR, the self refresh operation may not be performed on specific segments of all banks that are the same as each other, according to the segment information.

While example embodiments of the inventive concepts have been particularly shown and described with reference to some example embodiments, it will be understood that various changes in form and details may be made therein without departing from the spirit and scope of the following claims.

What is claimed is:

1. A semiconductor memory device performing a self refresh operation, the semiconductor memory device comprising:
a memory cell array including a plurality of banks each including a plurality of segments;
a mask information register configured to generate mask information by storing refresh information indicating a portion of the memory cell array on which the self refresh operation is not performed; and
a mask operation circuit configured to not perform the self refresh operation on the portion of the memory cell array in response to the mask information.

2. The semiconductor memory device of claim 1, wherein the refresh information includes bank information indicating that the self refresh operation is not performed on a bank corresponding to the bank information.

3. The semiconductor memory device of claim 1, wherein the refresh information includes segment information indicating that the self refresh operation is not performed on specific segments in all of the banks, the specific segments being the same for all of the banks.

4. The semiconductor memory device of claim 1, wherein the refresh information includes segment information indicating that the self refresh operation is not performed on selected segments in specific banks, at least one of the specific banks having at least one selected segment different from another of the specific banks.

5. The semiconductor memory device of claim 1, wherein the refresh information includes bank information, first segment information and second segment information and the mask information register comprises:
a bank mask information register configured to store bank information, the bank information indicating the bank on which the self refresh operation is not performed;
a first segment mask information register configured to store first segment information, the first segment information indicating specific segments in all banks on which the self refresh operation is not performed; and
a second segment mask information register configured to store second segment information, the second segment information indicating selected segments in specific banks on which the self refresh operation is not performed.

6. The semiconductor memory device of claim 5, wherein the bank information, the first segment information and the second segment information are provided from a mode register configured to allocate a received command address signal to the mask information register.

7. The semiconductor memory device of claim 1, further comprising:
a self refresh internal command generator configured to periodically generate an internal refresh signal in response to a self refresh command; and
an address counter configured to update a refresh address signal in response to the internal refresh signal.

8. The semiconductor memory device of claim 7, wherein the mask operation circuit detects a match or a mismatch between the refresh address signal and the mask information in response to the internal refresh signal to generate a match signal.

9. The semiconductor memory device of claim 8, wherein the match signal is provided to a switch unit that masks a bank signal or a segment signal corresponding to the refresh address signal.

10. A method of refreshing a semiconductor memory device including a plurality of banks each including a plurality of segments, the method comprising:
storing bank information and segment information indicating a bank and a segment on which a self refresh operation is not performed;
not performing the self refresh operation on a bank corresponding to the bank information, regardless of the segment information; and
not performing the self refresh operation on selected segments in specific banks that are different from each other, according to the segment information.

11. The method of claim 10, wherein the self refresh operation is not performed on specific segments of all banks that are the same as each other, according to the segment information.

12. The method of claim 10, wherein the bank information and the segment information are set with values allocated to command address signals loaded at rising edges of a clock signal and loaded at falling edges of the clock signal according to a mode register setting command.

13. The method of claim 10, further comprising:
periodically generating an internal refresh signal in response to a self refresh command; and
updating a refresh address signal in response to the internal refresh signal.

14. The method of claim 13, further comprising detecting a match or a mismatch between the refresh address signal and the bank information or the segment information in response to the internal refresh signal to generate a match signal.

15. The method of claim 14, further comprising masking a bank signal or a segment signal corresponding to the refresh address signal according to the match signal.

16. A semiconductor memory device performing a self refresh operation, the semiconductor memory device comprising:
a memory cell array including a plurality of banks, each bank including a plurality of segments; and
control logic configured to not perform the self refresh operation on selected segments in selected banks of the memory cell array.

17. The semiconductor memory device of claim 16, wherein the control logic is configured to set bank information indicating the selected banks.

18. The semiconductor memory device of claim 16, wherein the control logic is configured to set segment information indicating the selected segments, the segment information indicating the selected segments in all of the banks, the selected segments being the same for all of the banks.

19. The semiconductor memory device of claim 16, wherein the control logic is configured to set segment information indicating the selected segments, the segment information indicating the selected segments in the selected banks, at least one of the selected banks having at least one selected segment different from another of the specific banks.

20. The semiconductor memory device of claim 16, wherein the control logic comprises:
a bank mask information register configured to store bank information indicating the selected banks on which the self refresh operation is not performed;
a first segment mask information register configured to store first segment information indicating first specific segments in all banks on which the self refresh operation is not performed; and
a second segment mask information register configured to store second segment information indicating second specific segments in the selected banks on which the self refresh operation is not performed.
